(19) United States
(12) Patent Application Publication
(10) Pub. No.: US 2023/0289906 A1
(43) Pub. Date: Sep. 14, 2023

(54) EXERGY-BASED LIFE CYCLE ASSESSMENT OF BUILDINGS

(71) Applicant: University of Florida Research Foundation, Inc., Gainesville, FL (US)

(72) Inventors: Chinemelu J. ANUMBA, Gainesville, FL (US); Martin Nnamdi NWODO, Gainesville, FL (US)

(21) Appl. No.: 18/013,954

(22) PCT Filed: Jun. 30, 2021
(86) PCT No.: PCT/US2021/039802

§ 371 Date: Dec. 30, 2022

Related U.S. Application Data
(60) Provisional application No. 63/046,645, filed on Jun. 30, 2020.

(51) Int. Cl. G06Q 50/16; G06Q 10/0631; G06F 30/13

(52) U.S. Cl. CPC G06Q 50/163; G06Q 10/06315; G06F 30/13

(57) ABSTRACT

Various examples are provided related to exergy-based life cycle assessment of buildings. In one example, a method includes obtaining building parameters of a building including material mass values of the building; determining exergy-based life cycle assessment (Exe-LCA) values of the building using the building parameters; and modifying a building design using the Exe-LCA values. The Exe-LCA values can include life cycle resource depletion, life cycle exergy loss of emissions and/or total Exe-LCA of the building. In another example, a system includes a computing device and an ExeLCA analysis program that can cause the computing device to determine Exe-LCA values of a building based at least in part upon building parameters of the building and provide at least one modification of a design of the building based upon the Exe-LCA values.

### CROSS REFERENCE TO RELATED APPLICATIONS

This application claims priority to, and the benefit of, co-pending U.S. provisional application entitled “Exergy-Based Life Cycle Assessment of Buildings” having Ser. No. 63/046,645, filed Jun. 30, 2020, which is hereby incorporated by reference in its entirety.

### BACKGROUND

The building sector has significant environmental impact and is responsible for a substantial proportion of the world's energy and resource consumption. Buildings construction and operations together account for 36% of the global energy end-use and nearly 40% of energy-related carbon dioxide emissions. After the oil crises of the 1970′s, a major concern within building design and operation has been to reduce the need for operational energy and hence the need for oil-based heating and electricity. Due to the increasing awareness of environmental concerns and pressure from several government bodies, clients, and environmental activists, many studies have been conducted to reduce building energy consumption and its environmental impact.

### SUMMARY

Aspects of the present disclosure are related to exergy-based life cycle assessment of buildings. In one aspect, among others, a method comprises obtaining building parameters of a building, the building parameters comprising material mass values of the building; determining exergy-based life cycle assessment (Exe-LCA) values of the building based at least in part upon the building parameters, the Exe-LCA values comprising life cycle resource depletion, life cycle exergy loss of emissions and total Exe-LCA of the building; and modifying a design of the building based upon the Exe-LCA values, the modification producing modified building parameters of the building. In one or more aspects, the life cycle resource depletion can be determined based at least in part upon primary exergy demand (PExD) and materials exergy demand (MExD), wherein the MExD is based at least in part upon the material mass and material unit exergy. The PExD can be based at least in part upon primary energy demand, percentage fuel combination and gross calorific exergy to energy ratio. The primary energy demand can be determined by LCA.

In various aspects, the life cycle exergy loss of emissions can be determined based at least in part upon emission mass and emission unit exergy. The method can further comprise determining life cycle costing (LCC) values of the building, the LCC values comprising life cycle exergy cost of emission and total full environmental life cycle costing (feLCC) of the building. Determining the LCC values can comprise determining the life cycle exergy cost of emission based at least in part upon emission mass and emission unit exergy. Determining the LCC values can comprise determining the total feLCC based at least in part upon the life cycle exergy cost of emission and the life cycle resource depletion. In some aspects, the method can further comprise determining revised Exe-LCA values of the building based at least in part upon the modified building parameters, the revised Exe-LCA values comprising life cycle resource depletion, life cycle exergy loss of emissions and total Exe-LCA for the modified design of the building. The method can comprise providing modification recommendations based at least in part upon the Exe-LCA values, wherein the modification recommendations reduce the total Exe-LCA of the building.

In another aspect, a system comprises at least one computing device comprising a processor and memory; and an ExeLCA analysis program, where execution of the ExeLCA analysis program by the at least one computing device causes the at least one computing device to: determine exergy-based life cycle assessment (Exe-LCA) values of a building based at least in part upon building parameters of the building, the building parameters comprising material mass values of the building, the Exe-LCA values comprising life cycle resource depletion, life cycle exergy loss of emissions and total Exe-LCA of the building; and provide at least one modification of a design of the building based upon the Exe-LCA values, the at least one modification producing modified building parameters of the building. In one or more aspects, the life cycle resource depletion can be determined based at least in part upon primary exergy demand (PExD) and materials exergy demand (MExD), wherein the MExD is based at least in part upon the material mass and material unit exergy. The life cycle exergy loss of emissions can be determined based at least in part upon emission mass and emission unit exergy. The at least one modification can reduce the total Exe-LCA of the building.

In various aspects, execution of the ExeLCA analysis program can cause the at least one computing to determine life cycle costing (LCC) values of the building, the LCC values comprising life cycle exergy cost of emission and total full environmental life cycle costing (feLCC) of the building. Determining the LCC values can comprise determining the life cycle exergy cost of emission based at least in part upon emission mass and emission unit exergy. Determining the LCC values can comprise determining the total feLCC based at least in part upon the life cycle exergy cost of emission and the life cycle resource depletion. In some aspects, execution of the ExeLCA analysis program can cause the at least one computing to determine revised Exe-LCA values of the building based at least in part upon the modified building parameters, the revised Exe-LCA values comprising life cycle resource depletion, life cycle exergy loss of emissions and total Exe-LCA for the modified design of the building. Execution of the ExeLCA analysis program can cause the at least one computing to provide another modification of the design of the building based upon the revised Exe-LCA values, the other modification producing further modified building parameters of the building.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims. In addition, all optional and preferred features and modifications of the described embodiments are usable in all aspects of the disclosure taught herein. Furthermore, the individual features of the dependent claims, as well as all optional and preferred features and modifications of the described embodiments are combinable and interchangeable with one another.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIGS. 1A and 1B illustrate examples of node A0 and A1 IDEF-0 process models for exergy-based life cycle assessment (Exe-LCA), in accordance with various embodiments of the present disclosure.

FIGS. 2A and 2B illustrate examples of a questionnaire and results for evaluation of Exe-LCA, in accordance with various embodiments of the present disclosure.

FIGS. 3A and 3B illustrate tables comparing applications and programming languages, in accordance with various embodiments of the present disclosure.

FIG. 4 illustrates an example of a system architecture for an automated tool, in accordance with various embodiments of the present disclosure.

FIGS. 5A-5C illustrate examples of an interface for ExeLCA, in accordance with various embodiments of the present disclosure.

FIGS. 6A and 6B are table illustrating methodological disparities and case studies regarding LCA and life cycle costing (LCC), in accordance with various embodiments of the present disclosure.

FIGS. 7A-7C illustrate examples of node A0, A1 and A2 IDEF-0 process models incorporating LCC into, in accordance with various embodiments of the present disclosure.

FIG. 8 is a flowchart illustrating an example of the integration of exergy-based LCA into LCA provisions in Green Building Rating Systems (GBRS), in accordance with various embodiments of the present disclosure.

FIGS. 9A-9F illustrate examples of various scenarios of use for Exe-LCA of buildings, in accordance with various embodiments of the present disclosure.

FIG. 10 is a schematic block diagram of one example of a system employed for exergy-based LCA, in accordance with various embodiments of the present disclosure.

### DETAILED DESCRIPTION

Disclosed herein are various examples related to exergy-based life cycle assessment of buildings. Reference will now be made in detail to the description of the embodiments as illustrated in the drawings, wherein like reference numbers indicate like parts throughout the several views.

This disclosure describes the elements of the adapted cumulative exergy demand method for Exergy-based Life Cycle Assessment (Exe-LCA) of buildings. For buildings, cumulative exergy demand can be applied to the following basic elements in conventional LCA:
Primary Energy Demand to get Primary Exergy Demand
Material Mass to get Material Exergy Demand
Emission Mass to get Exergy Loss of Emissions
   These three elements will be discussed, the process model to represent the method for Exe-LCA of buildings described, and the potential benefits of a validated method for Exe-LCA of buildings with respect to conventional LCA of buildings presented.

### A Measure of Energetic Quality (Exergy) of Life Cycle Resource Use

In conventional LCA, resource use refers to both life cycle quantities of energy demand and materials, defined as the primary energy demand and material mass respectively. Unlike conventional LCA, the proposed Exe-LCA method considers the energetic quality (i.e. exergy) of life cycle resource use in measuring energy and material mass in terms of exergy demands. Exergy demand is a measure of resource depletion from nature.

Primary exergy demand. Primary exergy demand can be derived from primary energy demand. Primary energy is the energy embodied in natural resources before being transformed to intermediate and/or end-use energy. Examples of primary energy resources include coal, natural gas, sunlight, wind, rivers, biomass, geothermal, and nuclear energy resource. For combustible energy sources such as fossil fuels, primary energy can be calculated based on the calorific value of the fuel and the amount of fuel required to generate a given unit of electricity or heat. For non-combustible energy sources (e.g., renewable energy sources), primary energy can be calculated using either primary energy equivalencies or conversion efficiencies of the renewable energy source. More details on primary energy demand of renewable energy carriers can be found in “Primary Energy Demand of Renewable Energy Carriers” by Stoffregen and Schuller (http://www.thinkstep.com/system/files_force/downloads/white-paper/whitepaper_primary_energy_demand_of_renewable_energy_carriers.pdf?download=1, April 2014), which is hereby incorporated by reference in its entirety.

Since the energy sources for the buildings used for this discussion are fossil fuels (coal and natural gas), the derivation of primary exergy demand is based on primary energy demand of non-renewable energy carriers. For a given fuel source, the Primary Exergy Demand (PExD) is a product of Primary Energy Demand (PED) and gross calorific exergy-to-energy ratio (a).

PExD=PED*a*1 (1)

When two or more fuel sources are involved, the PExD is a cumulative of the product of PED, gross calorific exergy-to-energy ratio (a) and percentage combination (p) for each i of a total number (n) of the fuel sources.

$$PExD = {\sum }_{i = 1}^{n} P F D * {α}_{i} * {p}_{i} \qquad ( 2 )$$

Gross calorific value can be considered appropriate for the exergy-to-energy ratio instead of net calorific value because the former is produced under reversible condition, which is in accordance with exergy definition, while the latter maintains an irreversible condition. The PED is one of the outputs from conducting LCA of buildings using the conventional LCA tools.

Material exergy demand. Material exergy demand is a derivative of material mass. Material mass, in conventional LCA of buildings, is a quantity take-off (in kg) of materials in the building model under consideration. Material exergy demand, however, goes deeper to measure the material resource depletion equivalence of the material mass. For each building material (e.g. Aluminum, brick, concrete, steel, etc.), material exergy demand uses the unit exergy of the building material to estimate the resource depletion (such as chemical elements and ores) due to the material use.

Unit exergy of a material is a cumulative of the standard unit exergies of the substances that make up the material. Standard unit exergy of a substance is the unit exergy of the substance when the reference environment is composed of air at 298.15 K of temperature and 101.325 kPa of pressure. Chemical exergy is considered in this disclosure instead of physical exergy or any other types of exergy because chemical exergy depends on the temperature, pressure and composition of the system while other types of exergy do not consider composition of the substance. Therefore, chemical exergy evaluation is more holistic than that of the other exergy types. Values for standard chemical exergies of substances have been established (see, e.g., Exergy analysis of thermal, chemical, and metallurgical processes by Szargut et al., Hemisphere Publishing Corporation, 1988).

The standard chemical exergy of substances, as expected, is given in kJ/mol. To convert the unit of the standard chemical exergy of a substance to say, kJ/g, the value in kJ/mol is divided by the molar mass of the substance (g/mol). Since kJ/g holds the same value as MJ/kg, the latter is applied in this disclosure because material mass output from conventional LCA tools is in kg. Therefore, Material Exergy Demand (MExD) in MJ is a product of Material Mass (MM) in kg and Standard Chemical Exergy of the Material (SCExM) in MJ/kg.

MExD=MM*SCExM (3)

The Standard Chemical Exergy of a material (SCExM) in MJ/kg is a cumulative of the quotient of standard chemical exergy in kJ/mol as the dividend and molar mass in g/mol as the divisor for each substance i of a total number (n) of the substances that make up the material.

$$SCExM = {\sum }_{i = 1}^{n} \frac{{( SCExM in kJ / mol )}_{i}}{{( molar mass in g / mol )}_{i}} \qquad ( 4 )$$

Measure of Energetic Quality (Exergy) of Life Cycle Emissions. Like material exergy demand, the energetic quality of life cycle emissions can be estimated using Equations 3 and 4 but having material replaced with equivalent emission. In the context of LCA, it is referred to as Exergy Loss of Emission (ExLE) in this research. This is simply the exergy that is lost to the environment due to the emission of substances that cause environmental impacts in a building life cycle. Those emitted substances are said to have environmental impact potential because the actual degree of environmental harm that result from the emissions depends on regional ecosystem conditions and location of occurrence. An ecosystem region can be a large area of similar climate where similar biotic and abiotic interactions occur on similar sites. The units of potential environmental impacts are in kilograms of equivalent relative contribution (eq) of an emission commonly associated with that form of environmental impact (e.g., kg SO₂-eq for Acidification impact potential). In general, Exergy Loss of Emission for each i of the environmental impact potential in MJ-eq (ExLE) is a product of Emission Mass equivalence in kg-eq (EM) and Standard Chemical Exergy of Emission in MJ/kg (SCExE).

ExLEᵢ=EMᵢ*SCExEᵢ (5)

In turn, the SCExE is calculated as the quotient of standard chemical exergy in kJ/mol (i.e. dividend) and molar mass in g/mol (i.e. divisor).

$$S {CExE}_{i = 1} = \frac{{( SCExE in \frac{kJ}{mol} )}_{i}}{{( molar mass in \frac{g}{mol} )}_{i}} \qquad ( 6 )$$

The followings highlight the ExLE for the five common environmental impact potential according to the TRACI 2.1 characterization scheme, the environmental impact model developed by the US Environmental Protection Agency (EPA) to quantify environmental impact risk associated with emissions to the environment in the United States.

Acidification potential. Emissions such as sulfuric and nitric acids that cause acidifying effects to the environment result in acidification potential. The acidification potential is a measure of a molecule's capacity to increase the hydrogen ion (h⁺) concentration in the presence of water, thus decreasing the pH value. The media are air and water. Effects from acidification potential can cause damage to building materials, paints, lakes, streams, rivers, and various plants and animals. To estimate the ExLE for acidification, the amount of its equivalent relative contribution (in kg-SO₂-eq) can be multiplied by the standard chemical exergy of sulfur dioxide in MJ/kg (Equation 5). In turn, the standard chemical exergy of sulfur dioxide in MJ/kg can be calculated as the quotient of standard chemical exergy of sulfur dioxide in kJ/mol (i.e. dividend) and molar mass of sulfur dioxide in g/mol (i.e. divisor) (Equation 6). The amount of acidification potential (in kg-SO₂-eq) is one of the outputs from conducting LCA of buildings using the conventional LCA tools and it is a function of the mass of chemicals emitted to media, estimated potency of their stressors and/or their characterization factors.

Eutrophication potential. Eutrophication impact potential can be a measure of the effects of excessively high levels of macronutrients, the most important of which are nitrogen and phosphorus. Although nitrogen and phosphorus play an important role in the fertilization of agricultural lands and other vegetation, excessive releases of either of these substances may provide undesired effects on the environment. The media are air and water. Nitrogen is often more detrimental to coastal environments than phosphorus. To estimate the ExLE for eutrophication, the amount of its equivalent relative contribution (in kg-N-eq) can be multiplied by the standard chemical exergy of nitrogen in MJ/kg (Equation 5). In turn, the standard chemical exergy of nitrogen in MJ/kg can be calculated as the quotient of standard chemical exergy of nitrogen in kJ/mol (i.e. dividend) and molar mass of nitrogen in g/mol (i.e. divisor) (Equation 6).

Global warming potential. The global warming potential can be a measure of greenhouse gas emissions such as carbon dioxide and methane. These emissions can cause an increase in the absorption of emitted radiation by the earth, and thereby, increase the natural greenhouse effect. This may, in turn, have adverse impacts on ecosystem health, human health, and material welfare. The medium for global warming potential is air. TRACI 2.1 utilizes Global Warming Potential (GWP) for the calculation of the potency of greenhouse gases relative to CO₂, consistent with international acceptance. To estimate the ExLE for carbon dioxide, the amount of its equivalent relative contribution (in kg-CO₂-eq) can be multiplied by the standard chemical exergy of carbon dioxide in MJ/kg (Equation 5). In turn, the standard chemical exergy of carbon dioxide in MJ/kg can be calculated as the quotient of standard chemical exergy of carbon dioxide in kJ/mol (i.e. dividend) and molar mass of carbon dioxide in g/mol (i.e. divisor) (Equation 6).

Ozone depletion potential. Ozone depletion potential can be a measure of air emissions that contribute to the depletion of the stratospheric ozone layer. Depletion of the ozone causes higher levels of ultraviolet rays to reach the earth's surface with detrimental effects on humans and plants. Chlorofluorocarbons (CFCs), (which are used as refrigerants, foam blowing agents and solvents) and halons (which are used as fire extinguishing agents), have been reported to decrease stratospheric ozone level. To estimate the ExLE for CFCs, the amount of its equivalent relative contribution (in kg-CFC-11-eq) can be multiplied by the standard chemical exergy of CFC-11 in MJ/kg (Equation 5). In turn, the standard chemical exergy of CFC-11 in MJ/kg can be calculated as the quotient of standard chemical exergy of CFC-11 in kJ/mol (i.e. dividend) and molar mass of CFC-11 in g/mol (i.e. divisor) (Equation 6). However, many years ago the United States implemented a stringent regulation that led to a complete end of production of CFCs by 1996 and halons by 1994 and recovery of the ozone layer is expected in about 50 years.

Smog formation potential. Smog formation potential can be a measure of ground level ozone, caused by various chemical reactions between nitrogen oxides (NOx) and volatile organic compounds in sunlight. Human health effects from prolonged exposure to ground level ozone can result in a variety of respiratory issues, including increasing symptoms of bronchitis, asthma, and emphysema. In addition, permanent lung damage may result from prolonged exposure to ozone. The medium for ground level ozone is air. Tally uses a reference substance of ozone (O₃) since a total number of pollutants that are quantified in this category is nearly 1200 substances. To estimate the ExLE for ozone, the amount of its equivalent relative contribution (in kg-O₃-eq) can be multiplied by the standard chemical exergy of ozone in MJ/kg (Equation 5). In turn, the standard chemical exergy of ozone in MJ/kg can be calculated as the quotient of standard chemical exergy of ozone in kJ/mol (i.e. dividend) and molar mass of ozone in g/mol (i.e. divisor) (Equation 6).

### Process Model for Exergy-based LCA of Buildings

A method for exergy-based life cycle assessment of buildings in the form of a process model will now be presented. The section starts with a justification for the choice of the modeling technique, gives an overview of the selected modeling technique, and then presents a representation of the method for exergy-based life cycle assessment of buildings using the selected process modeling technique.

Choice of Modeling Technique. The two most used process modeling methodologies are: 1) Business Process Model and Notation (BPMN), and 2) Integration DEFinition Zero (IDEF-0). BPMN is semantically richer than other process modeling languages because it is based on revision of other notations including UML (Unified Modeling Language) and IDEF. IDEF-0, in contrast, is the most widely used of all inter-related areas of systems modeling and has proven to be suitable for use in construction.

Descriptions of business process model and notation. Business Process Modeling is the activity of representing processes of an enterprise in such a way that current operations (“as is”) can be analyzed and improved in future (“to be”). It is defined as the time period when workflow of a process is defined and/or modified electronically. Business Process Model and Notation (BPMN) is a graphical representation of business processes with wide range of modeling constructs. The complete BPMN specification can define 50 constructs plus attributes. It uses four basic elements:
Flow Objects such as events, activities, and gateways;
Connecting Objects (arrows);
Swim lanes to group activities into separate categories for different functional capabilities; and
Artefacts to display further related information such as processed data or comments.
   The primary goal of BPMN is to develop a notation that is flexible to business users: business analysts who develop the processes, technical developers who implement them, and business staff who monitor them.

Benefits and limitations of BPMN. The benefits of BPMN, based on the description, can include but are not limited to the following:
BPMN is semantically richer than other process modeling languages;
BPMN has the benefit of being flexible; its constructs comprise both core sets for generic process modeling and extended sets for specialized modeling; and
It is more comprehensive because its development was based on the revision of other notations including UML, IDEF, ebXML, RosettaNet, and Event-driven Process Chains.

The limitations of BPMN, based on the description, can include but are not limited to the following:
Based on representational analysis, BPMN lacks ontological completeness and clarity that can lead to problems with the use of the notation;
The complexity of BPMN in practice differs considerably from its theoretical complexity;
Filters are needed to specify the set of BPMN constructs to be used depending on modeling purpose; and
Other limitations, in terms of representation, can include construct deficit, redundancy, excess, and overload.

Descriptions of integration definition zero. Integration DEFinition Zero (IDEF-0) was designed to model the decisions, actions, and activities of an organization or system. It describes functions and their interfaces and enables hierarchical decomposition of details in a system. It uses only one notational construct: the ICOM (Input-Control-Output-Mechanism). This simplicity is perhaps its main strength. It uses natural and graphic languages to communicate meaning about a system. IDEF-0 models are static diagrams with no explicit or even implicit representation of time.

Benefits and limitations of IDEF-0. Based on the description, the benefits of IDEF-0 can include but are not limited to the following:
IDEF-0 is simpler to use than BPMN by using only one notational construct;
The technique provides more clarity using input-control-output-mechanism notation;
It produces more detailed models than the BPMN for better understanding of the steps involved in the process;
Its capability to reduce high-level descriptions into detailed low-level descriptions enhances automation of processes; and
In effect, it is becoming a standard for process modeling of the building process.

Based on the description, the limitations of IDEF-0 are an inability to model processes that are time dependent because of their static nature, and inability to depict the behavioral modeling perspectives.

Rationale for choice of modeling technique. Following the descriptions of the two commonly used process modeling methodologies, the rationale for the selection of IDEF-0 as the process modeling technique for the research includes the following:
IDEF-0 is suitable for use in construction and for modeling building process;
Since IDEF-0 describes functions and enables hierarchical decomposition of details, it is appropriate for use to represent the functional processes for exergy-based LCA method;
By using natural and graphic languages, IDEF-0 is suitable to clearly interpret and communicate the exergy-based LCA method;
Its capability to reduce high-level descriptions into detailed low-level descriptions make it easier to develop an automated calculation tool for exergy-based LCA of buildings; and
The proposed exergy-based LCA method is static and thus, does not require a behavioral or time dependent process modeling technique.

Representation of Method for Exergy-based LCA in IDEF-0 Modeling. There are five main functional elements in IDEF-0 process modeling technique, which are the following:
Function name;
Input;
Output;
Control; and
Mechanism.

The function or activity name can be regarded as the “independent variable” while input, output, control, and mechanism can be regarded as the “dependent variable” because their distributions across the hierarchical decomposition are determined by the function name.

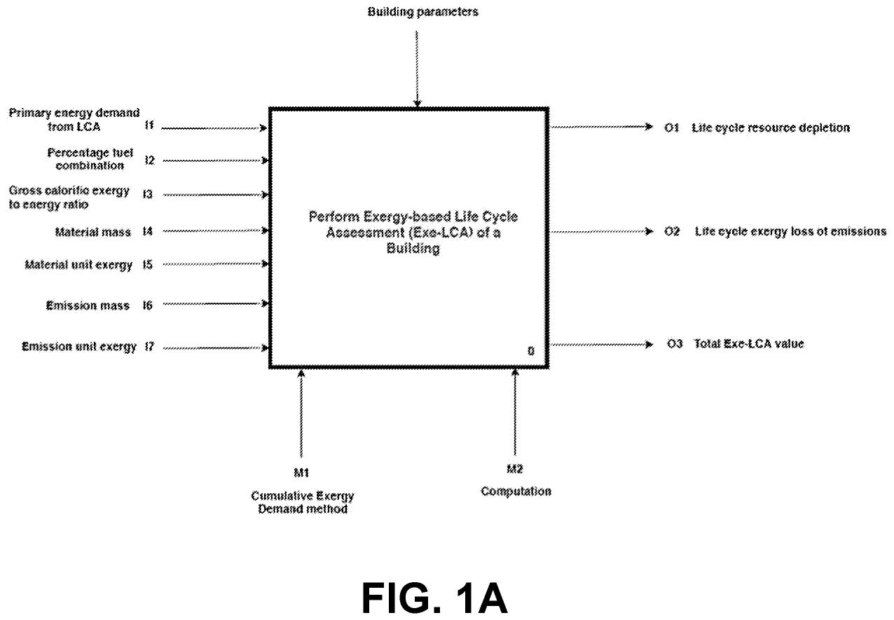

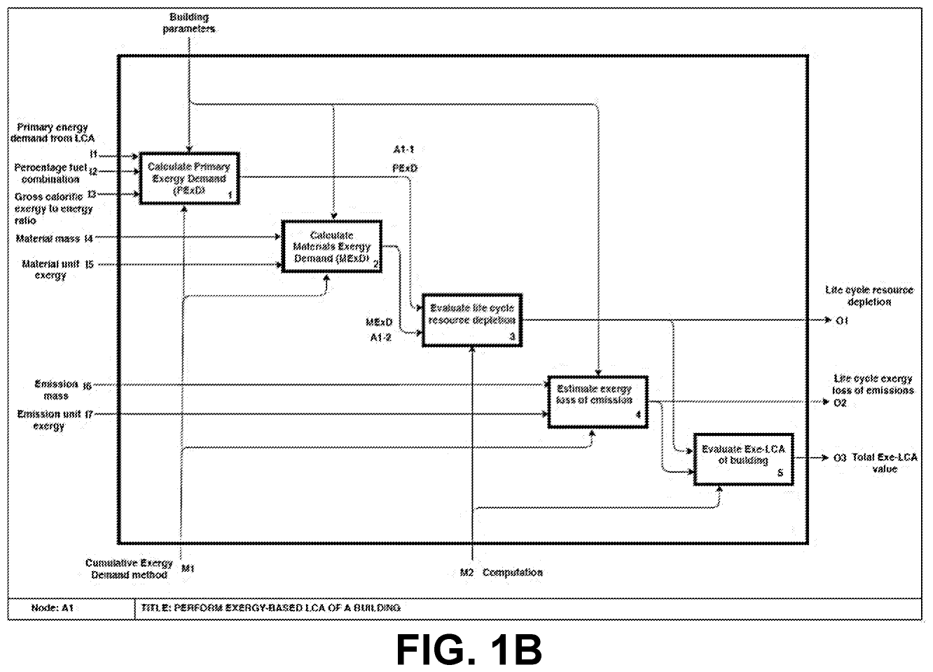

A representation of the method for exergy-based LCA of buildings is presented, first, in terms of the individual functional elements, and then in a combined representation. There are two nodes in the IDEF-0 model: Node A0 and Node A1. Both nodes have the same general inputs, outputs, controls, and mechanisms. However, Node A0 is the parent while Node A1 is the child in the hierarchical decomposition. This means that Node A1 is a low-level break down of high-level Node A0. In this disclosure, two nodes are enough to represent the proposed method for exergy-based LCA of buildings. FIGS. 1A and 1B illustrate examples of Node A0 (parent) and Node A1 (child) IDEF-0 process models of the proposed exergy-based LCA of buildings. Each of the functional elements has a letter identifier (I=input, M=mechanism, and O=output) and number identifier (1, 2, 3 . . . ).

Function names. The function name is a short description of the activity being performed and it is represented by the rectangular box. The function name usually starts with a verb to depict action or task being performed. In Node A0 of FIG. 1A, the function name is “Perform Exergy-based Life Cycle Assessment of a Building” with function number ‘0’ while the following are the function names and numbers in Node A1 of FIG. 1B:
Calculate Primary Exergy Demand (PExD)” with function number ‘1’;
Calculate Materials Exergy Demand (MExD)” with function number ‘2’;
Evaluate Life Cycle Resource Depletion” with function number ‘3’;
Estimate Exergy Loss of Emissions” with function number ‘4’; and
Evaluate Exergy-based LCA of Building” with function number ‘5’.

Inputs. Inputs in IDEF-0 model are represented by the arrows flowing into the left-hand side of an activity box. The general inputs for Nodes A0 and A1 are the same and from both conventional LCA model and exergy values of substances. They include the following:
Primary energy demand from LCA results—I1;
Percentage fuel combinations—I2;
Gross calorific exergy to energy ratio—I3;
Material mass—I4;
Material unit exergy—I5;
Emission mass—I6; and
Emission unit exergy—I7.
   However, the distribution of the inputs across activities are determined by the function being performed. For example, in Node A1 of FIG. 1B, the inputs for function number ‘1’ are I1, I2, and I3. The inputs for function number ‘2’ are I4 and I5. The inputs for function number ‘3’ are intermediate outputs from function numbers ‘1’ and ‘2’. Information about intermediate and main outputs are conveyed in the following. The inputs for function number ‘4’ are I6 and I7 while the outputs from function numbers ‘3’ and ‘4’ serve as the inputs for function number ‘5’.

Outputs. Outputs in IDEF-0 model are represented by arrows flowing out the right-hand side of an activity box. The main outputs for Nodes AO and Al are the same, which are the following:
Life cycle resource depletion—O1
Life cycle exergy loss of emissions—O2
Total Exe-LCA value—O3
   Since Node A1 of FIG. 1B has more details of the break down structure, it houses the following two intermediate outputs from function numbers ‘1’ and ‘2’ respectively:
Primary Exergy Demand (PExD)—A1-1
Material Exergy Demand (MExD)—A1-2

They are called intermediate outputs here because they act as inputs for function number ‘3’ and not part of the main outputs.

Controls. Controls in IDEF-0 model are represented by arrows flowing into the top side of an activity box. Although the manner of distribution is different, the controls for Nodes A0 and A1 of FIGS. 1A and 1B are the same and are made up of the building parameters such as life span, energy source, materials, design, orientation, and sensors.

The controls are the constraints on the activities. In other words, they are the conditions to be fulfilled for the activity to be performed. For example, the building parameters are constraints on function numbers ‘1’, ‘2’, and ‘4’ but are not constraints on function numbers ‘3’ and ‘5’. In fact, there are no controls or constraints on function numbers ‘3’ and ‘5’ because the performances of their functions are completely dependent on the performances of preceding functions.

Mechanisms. Arrows flowing into the bottom of an activity box represent the mechanism or resource to carry out the activity. While the distribution across activities differ, the mechanisms for Nodes A0 and A1 of FIGS. 1A and 1B are the same and are the following:
Cumulative Exergy Demand method—M1; and
Computation—M2.
   FIGS. 1A and 1B summarize an example of a method for exergy-based LCA in IDEF-0 modeling. The mechanism for function numbers ‘1’, ‘2’, and ‘4’ is M1 while the mechanism for function numbers ‘3’ and ‘5’ is M2. M2 simply provides a computing resource.

Validation of Method and Tool for Exergy-based LCA of Buildings

The validation of the method and tool for exergy-based LCA of buildings included the following:
Verification of the effectiveness of the method for exergy-based LCA of buildings as described;
Justification of the appropriateness of representation of the method in IDEF-0 process model;
Checking of the applicability of the exergy-based method to case study buildings and the usefulness and benefits of generated results;
Checking of the extent of improvement the method offers to conventional LCA of buildings; and
Appraising the ease of use and usefulness of the automated calculation tool.

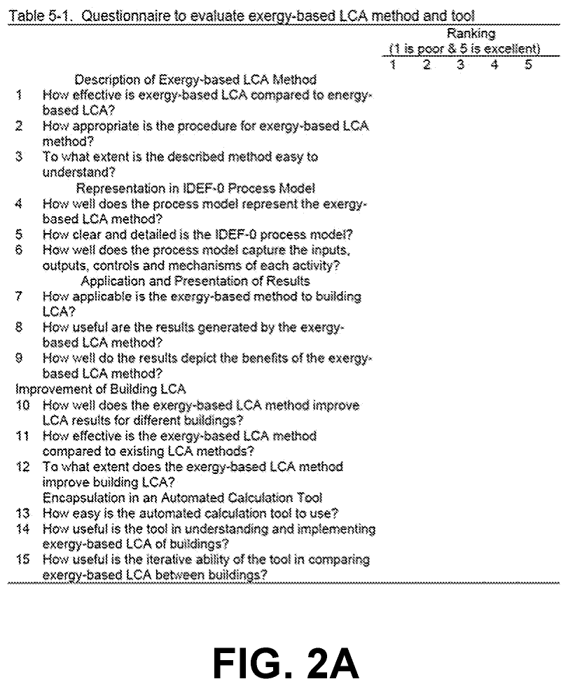

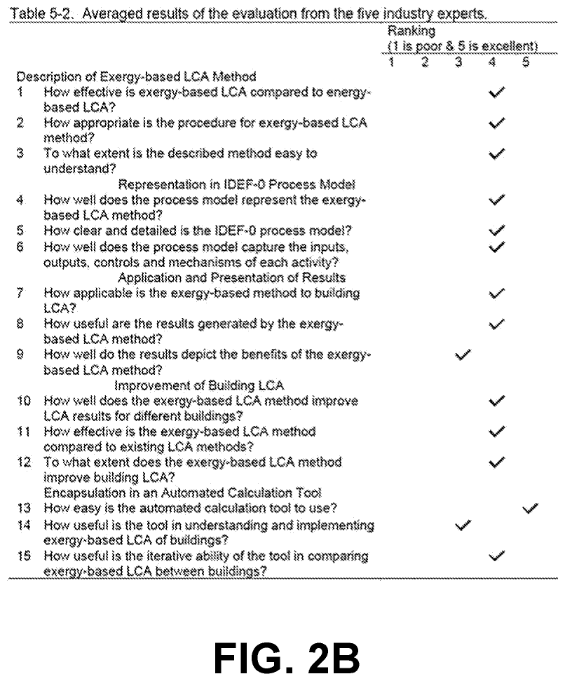

The process of validation of the method for exergy-based LCA of buildings involved an invitation to five industry and practicing experts on LCA and building sustainability for a presentation and discussion. The content of the presentation included a definition of LCA and exergy, the research problem and aim, the reasons for exergy-based LCA of buildings i.e. stating the theoretical benefits, a description of the proposed exergy-based LCA method, a representation of the method in IDEF-0 process model, application of the method to a case study building, presentation of results and the confirmed benefits and limitation of the proposed method, a presentation of the system architecture used to implement the proposed method in an automated calculation tool, and finally conclusions. After the presentation, the use of the automated calculation tool was demonstrated. A questionnaire (which has been duplicated in FIG. 2A) was distributed to evaluate the proposed method for exergy-based LCA of buildings as well as the automated calculation tool. The key considerations in the questionnaire are the description of the proposed exergy-based LCA method, its representation in IDEF-0 process modeling technique, the ease of use and usefulness of the automated calculation tool, application of the exergy-based LCA method to case study buildings and presentation of the results, the extent of improvement of building LCA by the proposed method in comparison to existing LCA methods.

The results of the evaluation from the five industry experts are averaged and presented in FIG. 2B. The rankings 1, 2, 3, 4, and 5 respectively signifies poor, fair, good, very good, and excellent. The results showde the following:
The effectiveness of the method for exergy-based LCA of buildings was verified as very good;
The appropriateness of representation of the method in IDEF-0 process model was also scored very good;
Applicability of the exergy-based method to case study buildings was scored between good and very good;
The extent of improvement the method offers to conventional LCA of buildings was scored very good; and
Appraise of ease of use and usefulness of the automated calculation tool is ranked between good and excellent.
   Potential Benefits with respect to Conventional LCA

The potential benefits of exergy-based LCA of buildings with respect to conventional LCA of buildings include the following:
The method for exergy-based LCA of buildings can consider the energy quality of the fuel sources to provide a more accurate estimation of fuel resource use;
Exergy-based LCA of buildings can provide a more in-depth building LCA by measuring energetic quality of life cycle emissions (i.e. Exergy Loss of Emissions) and materials resource depletion (i.e. Material Exergy Demand);
Exergy-based LCA can complement that of the conventional LCA, especially, to enable comparison of building LCA results through unit unification;
Since unit unification in exergy-based LCA of buildings is objective, there is a potential to eliminate subjectivity from normalization and weighting in conventional LCA; and
The method for exergy-based LCA of buildings provides a better integration potential for economic and social impacts.

### Automated Determination for Exergy-Based LCA of Building

An automated calculation tool was developed to demonstrate the method to determine the Exergy-based LCA (Exe-LCA) of buildings. The automated determination can include the following:
Encapsulate the method for Exe-LCA of buildings in an automated calculation tool;
Develop a tool for Exe-LCA of buildings for which its input values can be iterated;
Given the results from conventional LCA, use the tool to compare with results from Exe-LCA of buildings;
Use the tool to present the benefits of Exe-LCA over conventional LCA of buildings such as material exergy demand and ability to obtain a single objective function; and
Develop a tool that enables the practical use of Exe-LCA by building project team members.

### Choice of Development Environment

The challenge of choosing a tool development environment is twofold: the choice of either standalone application or web application to be used, and the choice of programming language to be employed to develop the tool. Also, the development environment was determined by the required functionality of the tool for Exe-LCA of buildings. The functionality of the tool, in turn, was guided by the objectives of the automated tool. The choice of the tool development environment is discussed further in the following sub-sections.

Standalone Application. A standalone application runs with or without Internet connectivity. The applications can be installed on a computing device such as, e.g., a computer or a local server. They can be installed from online websites and/or the use of a CD drive (or other non-transitory media) to complete the installation process. After the installation process, standalone applications can work on the system's local server or the computer. Since standalone applications are designed for computer operating systems, the system platform on which they run are determined prior to development. However, standalone application developers prefer to develop applications that support cross-platforms of computer operating systems so that users of various computer systems can utilize the applications. Various options for standalone application development include, for example:
Client-Server Applications, which run on local server of the computer system, but the access of information is on the remote server e.g. email, network printing, etc.;
Utilities and plug-ins for systems e.g. Tally plugin to Autodesk Revit 2019;
Collaborative applications, which serve a common task to the users while users can also interact with the common task e.g. construction project management tools such as Procore and PlanGrid;
Multi-media applications (e.g., computer games, virtual reality, etc.).
   Desirable features of standalone applications can include the following:
Standalone operation;
Runs mainly on local server;
Highly customizable to user's requirements; and
Functionality that is based on computer system property.

Web Application. A web application runs on a web server and is usually accessed through a web browser. Web applications can be developed without considering cross-platform computer operating systems because they run on web servers and the users can access the applications provided via the internet. Web application frameworks are usually used to support the development of web applications, including web services, web resources and web APIs. Examples of web application frameworks include, e.g., Ruby on Rails, Django, Angular, Express, Spring, etc. Features of web applications can include:
Web applications use search engines;
Flexible with design of user interfaces;
Dependent on the internet or remote server;
Cross-platform compliant; and
Dependent on available bandwidth.

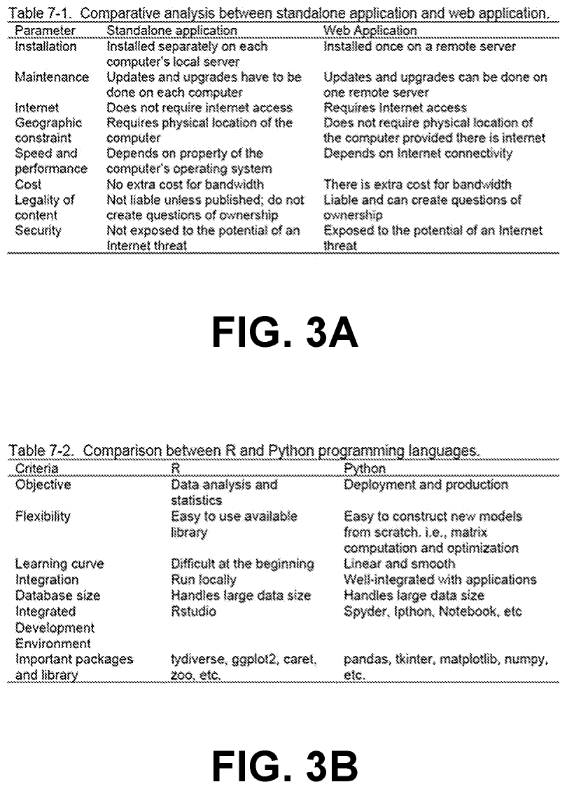

Selection of Application Type. The selection of application type (whether desktop or web application) for the automated calculation tool can depend on the goal and functionality of the program. A goal was to develop a program to demonstrate the implementation of the method for Exe-LCA of buildings. As indicated in the objectives of the automated calculation tool, it can be assumed that the user already has access to the results of conventional LCA of the building. Moreover, all the data for Exe-LCA of building can be included in the developed tool with no need to source the Web using the internet for any data. The table of FIG. 3A presents a comparative analysis between standalone and web applications based on a desk study. The developed tool is a simple program that takes a few seconds to install and maintain. The last three parameters in the table of FIG. 3A (i.e. cost, legality of content, and security) led to the preference of a standalone application over a web application, especially the added security. Given that the tool can perform its function in either of the application types, the use of standalone application is preferable to ensure the protection of the automated calculation tool.

‘R’ Programming Language. R is a programming language and software environment for statistical analysis, graphics representation and reporting. It is an interpreted computer language and allows integration with the procedures written in the C, C++, .Net, Python or FORTRAN languages for efficiency. Although R was developed by statisticians to make statistical data analysis easier, it has become suitable for a wide variety of nonstatistical tasks such as data processing and graphical visualization, and used in the fields of finance, natural language processing, genetics, biology, and market research. Features of R include the following:
Effective data handling and storage facility;
Integrated collection of tools for data analysis;
Integrated collection of tools for data analysis;
Vector-based language; vector is a row or column of numbers or text; and
Intepreted language i.e. runs code without a compiler.

‘Python’ Programming Language. Python is an object-oriented programming language, designed in C language, but has inbuilt modules and libraries to support many other different languages such as Java, C++, JSON, and R. By object-oriented, it means that Python has data structure as objects that have characteristics such as attributes and behaviors, and the objects can be placed in classes. Four major principles of Python as an object-oriented language include:
Encapsulation, which is the idea of bundling data and methods of data within one unit or class;
Data Abstraction, which is to hide all but the relevant data about an object to reduce complexity and increase efficiency; p1 Inheritance, which involves basing an object or class upon another object or class while retaining similar implementation; and
Polymorphism, which is the ability to process objects differently depending on their data type or class.
   Features of Python include the following:
Easy to learn, code, and read;
Support for Graphical User Interface (GUI);
Object-oriented;
High level and thus, no need to remember system architecture or manage memory;
Interpreted i.e. source code is run line by line and therefore, easy to debug; and
Embeddable and extensible to other languages.

Selection of Programming Language. Based on criteria such as expected outputs of the automated calculation tool, available resources and learning curve of programming language, and potential use of the tool, R and Python programming languages were considered. The table of FIG. 3B provides a comparison between the R and Python programming languages. Python was selected instead of R for the following reasons:
Python better supports the expected outputs of the automated calculation tool;
Python supports the functionality of the tool as a GUI standalone application;
Python has a linear and smooth learning curve, unlike R; and
Tools using Python can easily be deployed and produced, if needed.
   Moreover, Python codes are easier to maintain and more robust than R.

### System Architecture

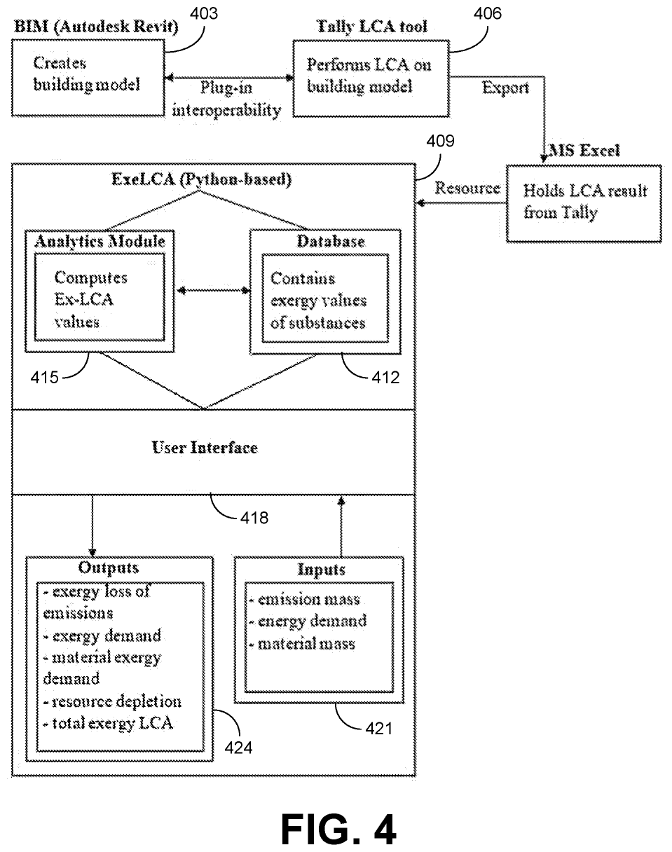

Referring to FIG. 4, shown is a schematic presenting an example of the system architecture for the development and operation of the automated calculation tool. The system architecture of FIG. 4 comprises tools such as a building information modeling (BIM) tool 403, an LCA tool 406, and the automated calculation tool (called “ExeLCA”) 409. The BIM tool 403 can create a digital representation of the physical and functional characteristics of the building in consideration. In addition, it can produce the take-off quantities of the building for use by the LCA tool 406. The LCA tool 406 can perform conventional LCA on the building model and produce results to be used for Exe-LCA of the building model in ExeLCA 409. The ExeLCA tool 409 performs Exe-LCA of the building model using its modules such as database, analytics, and user interface for inputs and outputs. In this disclosure, Autodesk Revit was used as the BIM tool 403 and Tally was used as the LCA tool 406. Autodesk Revit and Tally can be considered as an enabling external resource for the automated calculation tool. This is because the choice of enabling tools can vary, provided they produce the needed resource for the automated calculation tool (e.g., LCA results).

The database module 412 can contain the values of standard chemical exergy of emissions, factor for the product of gross calorific exergy-to-energy ratios and percentage fuel combinations, as well as the values of chemical exergy of common building materials. The analytics module 415 can get input values from the user and interacts with the database module 412 to compute values for exergy loss of emissions, primary exergy demand, material exergy demand, resource depletion, and total Exe-LCA. The user interface 418 can include entry fields 421 for the user to input results from a conventional LCA of buildings such as, e.g., emission mass, primary energy demand, and material mass. In addition, the user interface 418 can include output field labels 424 to display the results sent by the analytics module.

### Design and Operation of the Automated Calculation Tool

The system architecture guided the design and operation of the ExeLCA tool 409. A desk study was conducted to design the graphical user interface (GUI) for the standalone application using a tkinter package, which is a standard Python interface to the Tk GUI toolkit. The GUI of ExeLCA in tkinter package was designed as follows:
The root window is titled “ExeLCA” and has a frame that contains a logo, a header that reads “Welcome to ExeLCA!” and a label message to describe the function of the tool;
In addition, the window contains two vertically stacked frames: an input frame and an output frame;
The input frame contains the following: A header that reads “Input Values (LCA)”, two sub-headers: one that reads “Emission Mass/Energy Demand” and the other, “Material Mass (kg)”, labels and entry fields to ask for user inputs in terms of LCA, and material mass, and a “Calculate” button and a “Clear” button; and
The output frame contains the following: A header that reads “Output Values (Exe-LCA)”, two sub-headers: one that reads “Exergy Loss of Emissions/Exergy Demand” and the other, “Material Exergy Demand (MJ)”, labels and output fields to display outputs in terms of Exe-LCA (green colored fonts), and materials exergy demand, a label and an output field to display output for “Resource Depletion”, and a label and an output field to display “Total Exe-LCA”.

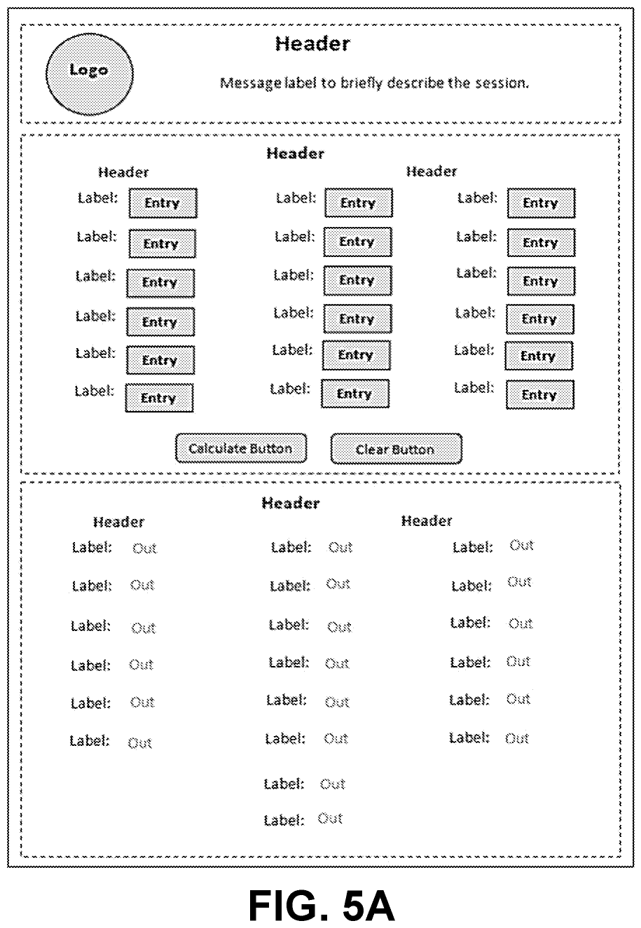

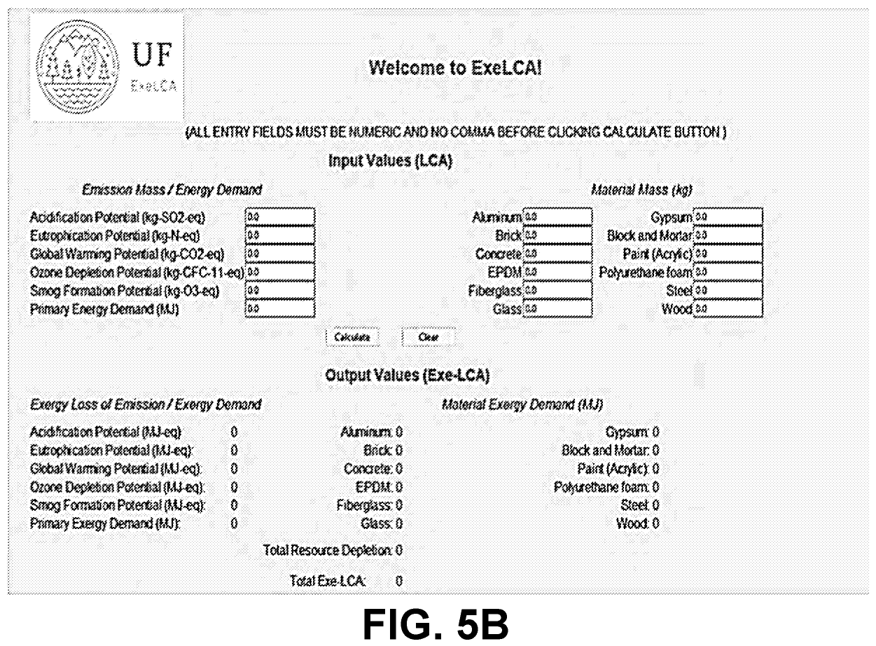

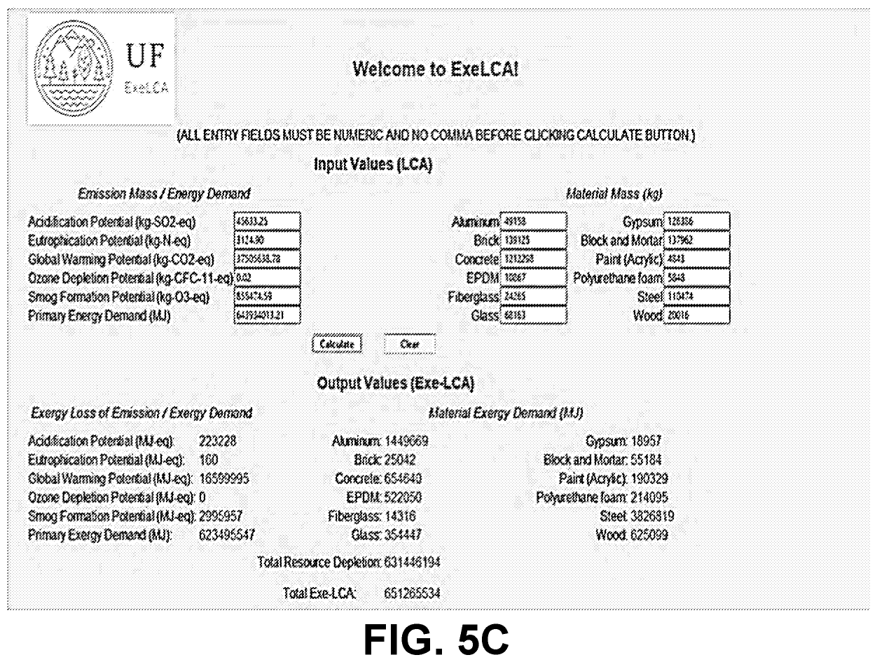

FIG. 5A shows an example of the design of a ExeLCA GUI in tkinter. Each of the objects in the GUI is called a widget and the widgets can be arranged in a parent-to-child relationship. The following illustrates an example of the parent-to-child relationships for creating the widgets in ExeLCA:
Root: ExeLCA
   Frame: header
      Label: logo (image)
      Label: header
      Label: message
   Frame: input
      Label: header
      Label: sub-header1
      Label: sub-header2
      Label: entries1-18
      Button: calculate
      Button: clear
   Frame: output
      Label: header
      Label: sub-header1
      Label: sub-header2
      Label: entries out1-18
      Label: out19
      Label: out20

After developing and successfully running the ExeLCA python file (e.g., the computer coding), the python file was converted into a standalone executable file for operation. FIG. 5B shows a screenshot of operation of an example of the GUI of the standalone application when it is opened while FIG. 5C shows a screenshot of its operation when used to conduct the Exe-LCA of a building model (e.g., Rinker Hall). The ExeLCA can accept numeric entries with no comma with all entries holding a value before selecting the ‘Calculate’ button.

The automated calculation tool demonstrates the performance of exergy-based LCA of building from conventional LCA with the same energy sources. In effect, the following assumptions were used and held true for the automated calculation tool:
The energy sources are coal and natural gas with fuel percentage contribution of 31% and 69% respectively, according to 2013 Florida electric power generation;
The environmental impacts are limited to six common impact categories such as acidification, eutrophication, global warming, ozone depletion, and smog formation potential, as well as energy demand;
The building materials are limited to top 12 common materials from the on-campus case study buildings, selected by mass;
Since the tool requires that conventional LCA be completed first, it is independent of specifications such as the utilized LCA method, assumptions, and life spans;
The kilogram equivalent units of impact categories for LCA follow the convention in existing LCA tools; and
The tool was designed for use in the US, but may be extended to other locations.

### Considerations in the Use of Exergy-Based LCA in the Building Industry

Practical considerations in the use of exergy-based LCA in the building industry. The identification of the practical considerations is based on the following:
The improvement of LCA of buildings for better informed decision-making;
The improvement of whole building LCA provisions in green building rating systems; and
Provision of guidelines for use of exergy-based LCA method in the building industry.

For the improvement of LCA of buildings for better informed decision-making and designs, life cycle costing can be selected to account for the economic aspect of building sustainability as LCA accounts for the environmental aspect. In addition, the methodology for life cycle costing of buildings can be better developed compared to that for the social aspect of building sustainability. With the increased global awareness and concerns about the life cycle environmental impacts of buildings, many building owners and clients register their buildings for green building ratings, for which LCA is usually an option to earn points. How exergy-based LCA method can be used to improve the existing LCA provisions in green building rating systems will now be discussed. Guidelines are provided to building designers for the use of exergy-based LCA method to evaluate both life cycle resource use and life cycle emissions in a building life span.

Incorporation of Life Cycle Costing into Exergy-based LCA

A process model is now presented for the incorporation of life cycle costing into Exe-LCA, as one of the practical considerations in the use of Exe-LCA in the building industry. An introduction to LCC and LCC of buildings is first presented to determine the LCC type most suitable to the proposed method for Exe-LCA of buildings. The methodological disparities between LCA and LCC are discussed with a summary of ongoing studies on integration of LCA and LCC of buildings. The proposed process model for the incorporation of LCC into Exe-LCA is presented and its benefits outlined.

Introduction to Life Cycle Costing of Buildings. The term life cycle costing (LCC) was first used by the US Department of Defense to enhance cost effectiveness in the acquisition of high-cost military equipment such as planes and tanks. It refers to an analysis technique that encompasses all costs associated with a product from its inception to its disposal. When the product is a building, LCC can be used to estimate relevant present value costs in the lifespan of the building, including initial capital cost (IC), replacement cost (Repl), operating, maintenance and repair costs (OM&R), and residual cost (Res). Equations 7 to 9 present formulae for calculating LCC:

$$L CC = IC + D P {V}_{Repl} + {DPV}_{O M \& R} - D P {V}_{Res} \qquad ( 7 )$$

$$DPV = \frac{F C}{{( 1 + d )}^{n}} \qquad ( 8 )$$

$$FC = PC * {( 1 + f )}^{n} \qquad ( 9 )$$

Where, LCC is the total life cycle cost in Discounted Present Value (DPV) of money, FC is the future cost, PC is the present cost, d is the discount rate, f is the inflation rate, and n is the number of years.

To deal with financial, environmental, and social considerations, four LCC types can be introduced, namely:
Financial Life Cycle Costing, fLCC;
Environmental Life Cycle Costing, eLCC;
Full Environmental Life Cycle Costing, feLCC; and
Societal Life Cycle Costing, sLCC.

Financial Life Cycle Costing (fLCC) categorizes conventional LCC that focuses on internalized economic investments from one actor, which excludes environmental costs and external end-of-life costs. It is limited to the economic lifetime of the investment. Examples of costs included in fLCC are, e.g., discounted present values of capital costs, income and expenses, ownership cost, etc.

Environmental Life Cycle Costing (eLCC) builds upon data from fLCC and extends it to life cycle costs borne by other actors such as, e.g., waste disposal costs, carbon dioxide taxes, global warming adaptation costs, etc. Like fLCC, the focus of eLCC is internalized cash flows but, in contrast, eLCC uses a steady state cost model in which all variables remain constant over time.

Full Environmental Life Cycle Costing (feLCC) was introduced to dissociate eLCC from being considered as an equivalent of environmental LCA. In feLCC, eLCC is extended with monetized, non-internalized environmental costs that can be identified by an environmental assessment method such as LCA. While in eLCC there is no conversion from environmental emissions to monetary measures, the conversion from environmental impacts to monetary measures in feLCC is not always straightforward. This is probably because each category of environmental impact in LCA, although represented by an equivalent measure of emission, is caused by several emissions.

In Societal Life Cycle Costing (sLCC), all costs borne by members of a defined society over the life span of a product system are included. That is, impacts such as public health and human wellbeing are quantified and translated into monetized measures at discounted rates.

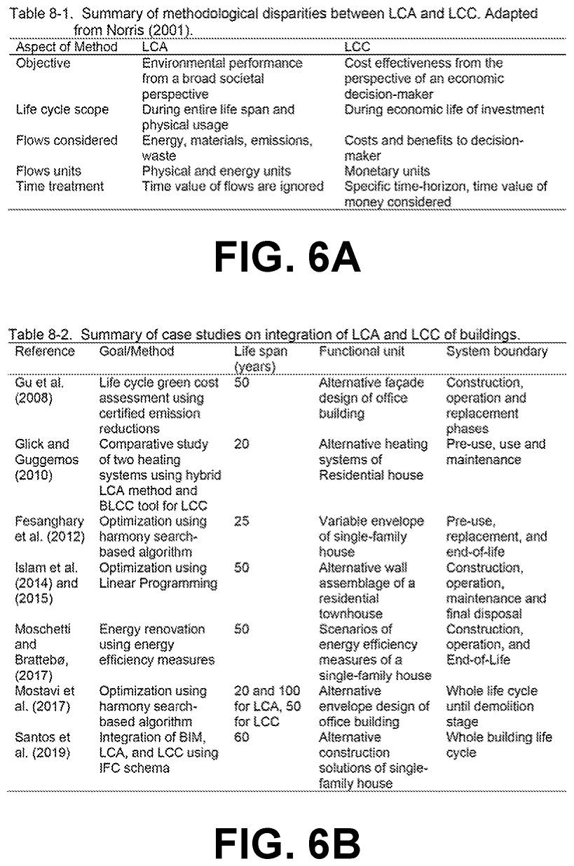

Methodological Disparity between LCA and LCC. Although economic considerations may be beneficial in industry applications of LCA, economic aspects of decision-making are neither within the scope of developed LCA methodology nor are they adequately addressed by existing LCA tools. The reason why LCC is not well addressed by LCA may be attributed to their methodological differences. The root of their differences may lie in the fact that they both tend to provide answers to different issues. While LCA evaluates environmental performance of alternative product systems from a broad societal perspective, LCC evaluates cost effectiveness of alternative investments and business decisions from the perspective of an economic decision-maker. The table in FIG. 6A summarizes the methodological differences between LCA and LCC. These disparities limit the relevance of LCA for decision-making, make it difficult to establish trade-offs between LCA and LCC, and can result in LCC missing important costs that can only be found within the scope of LCA, and vice versa.

It has been recommended that any approach to fully bridge the gap between LCA and LCC should overcome the methodological disparities in the table of FIG. 6A, in addition to solving risk and uncertainty issues. However, this recommendation appears to be referring to the financial LCC type as opposed to other LCC types such as environmental LCC, full environmental LCC, and social LCC.

In another view, there are two complimentary and ongoing developments, which can provide the means to better exploit the potential of LCA for decision-making, while maintaining its validity and scientific property. These two developments can be paraphrased as:
Development of implementation processes to close the gap between existing methodologies and tools; and
Extension of life cycle environmental impact assessment to also address economic and social aspects within sustainability.

This view aligns with the potential goal for exergy-based LCA of buildings. In fact, the method for Exe-LCA of buildings, and as a result, the ExeLCA tool, can aid with the implementation process of LCA of buildings, in addition to having the potential to incorporate economic and social aspects of sustainability. This is because Exe-LCA solves one of the major issues of quantifying sustainable development—metrics, by an objective unification of assessment units. Although the methodological basis for social aspect of sustainability is still in its infancy relative to advancements in LCA and LCC, the three aspects of sustainability can be computed and compared using similar system boundaries and functional units while maintaining their independence.

There are several existing studies on the integration of LCA and LCC, but few studies have applied the approaches to case study buildings. The table of FIG. 6B summarizes studies on integration of LCA and LCC as applied to case study buildings in terms of goal/method, life span, functional unit, and system boundary. The presented studies are limited to articles that considered at least one impact category in conducting LCA of buildings while integrating with LCC.

The studies on integration of LCA and LCC of buildings (FIG. 6B) show that using similar assumptions, functional units, and system boundaries for both LCA and LCC makes the integration feasible. However, it is not clear whether the utilized methods in the studies fully bridged the methodological disparities (FIG. 6A) between LCA and LCC in order to correctly use the term ‘integration’. In this disclosure, the use of the term ‘incorporate’ is more appropriate than the use of the term ‘integrate’ to show that LCC is included in Exe-LCA as part of a whole especially when the research goal is not to overcome the existing methodological disparities between LCA and LCC. The choice of a suitable LCC type for the incorporation can impact the process. A process model for incorporating LCC into Exe-LCA of buildings is now presented.

Process Model to Incorporate LCC into Exe-LCA of Buildings and Benefits. The proposed IDEF-0 process model to incorporate LCC into Exe-LCA of buildings will now be presented. Out of the four LCC types discussed, the feLCC can be utilized in the process model. Although the conversion from environmental impacts to monetary measures in feLCC is not always straightforward, this limitation can be overcome by using the cost of a variable emission unit, referred to as the Emission Trading Unit (ETU), for each of the emissions that cause the environmental impact. The price of ETU varies with load of emissions that make up an impact category in Exe-LCA and can be regulated by a protocol. For example, if sulfuric and nitric acids are identified as the emissions in acidification potential, and their loads are, e.g., 50 MJ and 30 MJ respectively, then based on the agreed price of ETU for each of the emissions in dollar/MJ, the monetary measure of acidification potential can be evaluated by computation. Equations 10 to 11 give formulae that can be used for evaluating the Life Cycle Exergy Cost of Emission (LCExCE) for each emission and for a combination of emissions.

$$LCExCE ( \$ ) = Emission ( MJ ) * ETU ( \frac{\$}{MJ} ) \qquad ( 10 )$$

$$Total LCExCE ( \$ ) = {\sum }_{i = 1}^{ne} {LCExCE}_{i} \qquad ( 11 )$$

Where i is the first emission in an impact category and ne is the number of emissions.

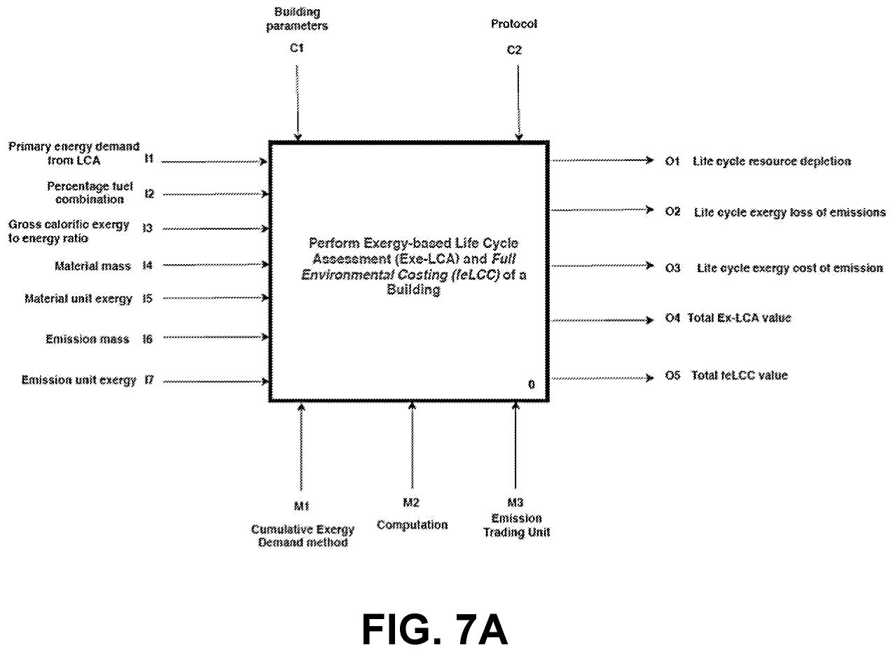

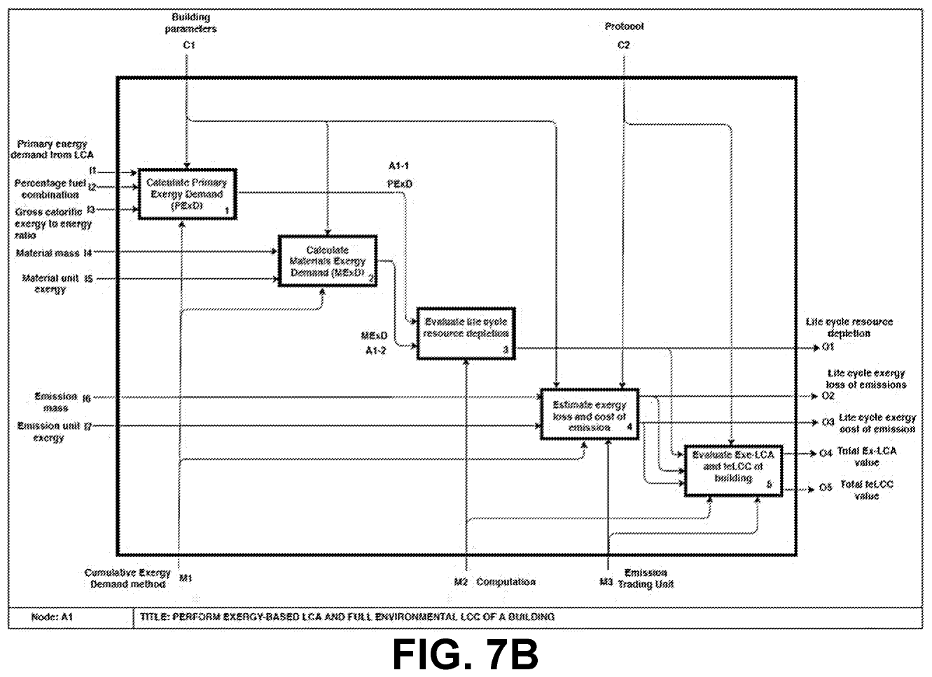

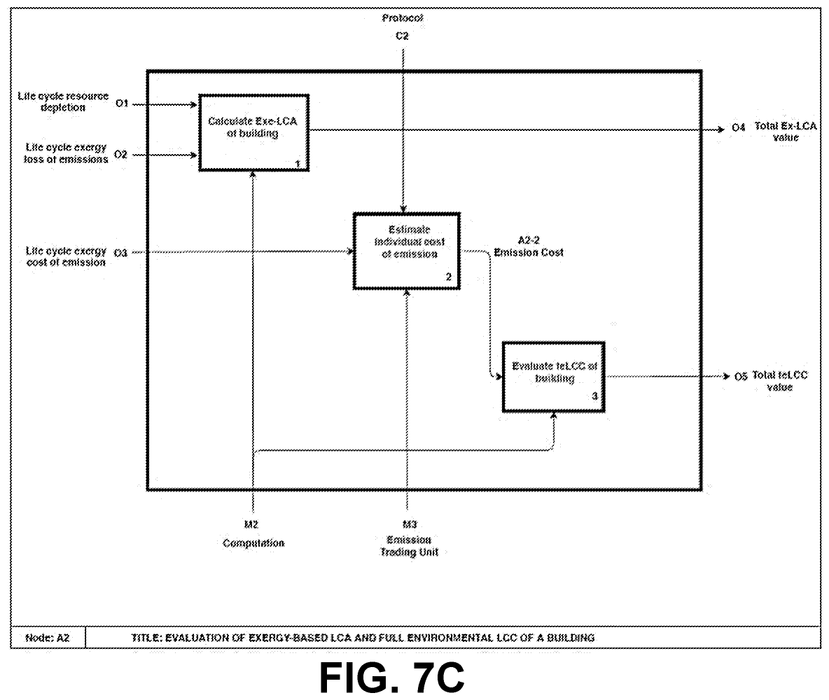

The parent (i.e. Node A0) and child (i.e. Node A1) IDEF-0 process model to incorporate LCC into Exe-LCA of buildings are shown in FIGS. 7A and 7B. FIG. 7A illustrates an example of a parent process model (Node A0) to incorporate the feLCC into Exe-LCA method and FIG. 7B illustrates an example of a child process model (Node A1) to incorporate feLCC into Exe-LCA method. While ETU has been developed for global warming potential category, which is a category of interest per the Kyoto Protocol, full utilization of the developed process model for the incorporation of feLCC into Exe-LCA of buildings is contingent upon developing the ETUs for the other five basic impact categories: acidification, eutrophication, ozone depletion, and smog formation potential, as well as primary energy/exergy demand.

FIG. 7C shows an example of the breakdown of function number five (Node A2) to show steps to incorporate feLCC into the Exe-LCA method. The difference between the process model for Exe-LCA of buildings and that for the incorporation of feLCC into Exe-LCA of building is the inclusion of the following parameters:
Life cycle exergy cost of emissions—O3;
Total feLCC value—O5;
Protocol—O2; and
Emission Trading Unit—M3.
   The potential benefits of incorporating feLCC into method for Exe-LCA of buildings include the following:
It shows how life cycle environmental impacts can objectively be converted into monetary measures while maintaining their independent significance;
With full environmental LCC and Exe-LCA values, a better decision-making can be made respectively on environmental cost and impact of building sustainability;
The incorporation of feLCC and Exe-LCA increases the motivation to incorporate the social aspect (e.g. in terms of cost) of sustainability into building assessment;
The use of Exe-LCA method enables the consideration of all the relevant environmental impact categories while incorporating feLCC; and
The incorporation of feLCC into Exe-LCA can be encapsulated in a software prototype as represented in the IDEF-0 process model.

### LCA Provisions in Green Building Rating Systems and Opportunity for Improvement

The current provisions for whole building LCA in Green Building Rating Systems (GBRS), the challenges of the current provisions, and potential of exergy-based LCA of buildings to solve some of the challenges in the current provisions are now presented. Three most widely used GBRS were investigated, namely: LEED, Building Research Establishment Environmental Assessment Methodology (BREEAM), and Green Globes.

LCA and Green Building Rating Systems. The demand for improved sustainable buildings, which have less material use and environmental impact, has led to the emergence of GBRS to create a new perception of building sustainability and marketability from the stakeholders' point of view. GBRS drives stakeholders such as owners, designers, and builders to create perceived or actual environmentally preferable buildings. The terms “rating system” and “certification” are commonly used interchangeably. There are other building assessment systems such as building standards, which set the guidelines and criteria against which a product can be assessed. Examples of organizations that create building standards are ANSI (American National Standards Institute), ASTM (American Society for Testing and Materials), and ASHRAE (The American Society of Heating, Refrigerating and Air-Conditioning Engineers).

Green building codes are another building assessment system, which drives building standards towards improved sustainability and performance. The unique difference between green building codes and GBRS is that codes are mandatory. Examples of green building codes are International Green Construction Code (IgCC) and the California Green Building Standards Code (CALGreen Code). Rating systems or certifications confirm that a building or its products meet defined criteria of a standard or code. In effect, there are green product certifications such as Energy Star, WaterSense, Forest Stewardship Council, and Green Seal; and there are GBRS, which is the focus for further discussion. GBRS broaden the scope beyond the product to consider the project as a whole and reward relative levels of compliance or performance with specific environmental goals and requirements. ISO supports the governance of standards and rating systems by defining and developing worldwide standards that often form the basis of industry norms.

Out of the building assessment systems, GBRS was selected to be investigated because of the following reasons:
The scope is beyond the product to consider the building project as a whole;
Unlike codes and standards that are either mandatory or norms, GBRS are more adaptable;
GBRS are designed to reduce the overall impact of the built environment on human health and the natural environment; and
GBRS address every project type from single-family houses and commercial buildings to entire neighborhoods.
   Examples of GBRS include: BREEAM, LEED, Green Globes, Living Building Challenge, SITES, and Passive House Institute US. The following GBRS that have LCA provisions are investigated due to their similarity in origin and popularity in Northern America:
LEED by the USGBC;
BREEAM by the U.K. Building Research Establishment; and
Green Globes by Green Building Initiative.

A possible credit reward of five points was included for the first time in LEEDv4, which was released in 2013, under “Building life-cycle impact reduction” credit category. As specified on the USGBC website for new construction buildings, the intent of the credit category is to encourage adaptive reuse and optimization of the environmental performance of products and materials. The requirements are to demonstrate reduced environmental effects during initial project decision-making by reusing existing building resources or demonstrate a reduction in materials use through LCA. To earn credits, one of the following options are achieved:
Historic building reuse (5 points);
Renovation of abandoned or blighted building (5 points);
Building and material reuse (2-4 points); or
Whole building LCA (3 points).
   The focus here is on the last option—whole building LCA. To earn the points, the following conditions were specified to be met:
LCA of the project's structure and enclosure would be conducted;
It should demonstrate a minimum of 10% reduction, compared with a baseline building, in at least three of the six impact categories listed below:
   Global warming potential (greenhouse gases), in kg CO₂e;
   Depletion of the stratospheric ozone layer, in kg CFC-11;
   Acidification of land and water sources, in moles H+ or kg SO₂;
   Eutrophication, in kg nitrogen or kg phosphate;
   Formation of tropospheric ozone, in kg NOx, kg O₃ eq, or kg ethene; and
   Depletion of nonrenewable energy resources, in MJ;
One of the impact categories is global warming potential; and
Use the same LCA software tools and data sets to evaluate both the baseline building and the proposed building and report all listed impact categories.

BREEAM UK New Construction completely replaced the old Green Guide approach with building LCA in 2018 because LCA was, after then, considered less of a specialist technique for most design teams. In BREEAM, a possible credit reward of seven points is awarded under “Mat 01—Environmental impacts from construction products—Building life cycle assessment” credit category. Either an IMPACT Compliant tool recognized by BREEAM is used or the BREEAM simplified building LCA tool is used to earn the points. The options are outlined in the following with possible credit awards for concept and technical designs of buildings:
Concept design only: up to five points plus one point for exemplary depending on whether the recognized LCA tool is suitable for superstructure in addition to substructure, hard landscaping and/or core building services;
Technical design only: up to three points depending on how well a recognized LCA tool handles the superstructure criteria;
Concept design and Technical design: up to seven points plus one point for exemplary by using the BREEAM simplified building LCA tool for the superstructure criteria at the concept design stage, or use of recognized LCA tool at either concept design stage or technical stage or both, in addition to the tool being suitable for the substructure, hard landscaping and/or core building services.

In Green Globes, whole building LCA is placed under the Materials section and has a maximum of 30 points achievable. According to Green Globes for New Construction 2019 Technical Reference Manual, to earn the points, the project team evaluates a minimum of two different building designs using ASTM E2921-13. In addition, the team should report the following life cycle impact indicators and select the building with the lower environmental impact:
Global warming potential/climate change;
Acidification potential;
Eutrophication potential;
Ozone depletion potential; and
Smog potential.

After then, the proposed final design of the building with the lower anticipated environmental impact should achieve the following performance targets compared to the reference design:
A minimum of five percent reduction each, for at least three impact indicators, one of which is global warming potential; and
No other impact indicator exceeds the reference design by more than five percent.
   Percentage reduction is demonstrated by adding at least three impact indicators. For example, greater or equal to 25 percent reduction earns a full score of 30 points, 22 percent reduction earns a score of 24 points, 15 percent reduction earns a score of 10 points, and less than 15 percent reduction earns zero points.

Challenges and Opportunity for Whole Building LCA Provisions in GBRS. The challenges of LCA provisions in GBRS and the potential of exergy-based LCA method to overcome the challenges of LCA provisions in GBRS is next presented. Based on the overview of GBRS that have LCA provisions, the following challenges were observed in conventional practice:
Fulfilling the conditions of GBRS involves repeated iteration of LCA of a building;
Selection of the building with a true lower environmental impact is difficult because of the variations in units;
Discerning the choice of impact categories for effective reduction of environmental impacts is a challenge because of difficulty in their comparisons;
To be able to effectively compare a building LCA design with its reference design, a user will have to use normalization and weighting, which introduces increased subjectivity in the LCA; and
It can be demanding in time and effort to interpret the results of a building LCA relative to its reference design, considering iteration demands.
   The potential of exergy-based LCA of buildings, including its confirmed benefits, to overcome the challenges of whole building LCA provisions in GBRS include the following:
The ability of exergy-based LCA to express life cycle environmental impacts as a single objective function enables the selection of the building with the lower environmental impact for further impact reduction analysis;
The use of a common scale of values in exergy-based LCA of buildings makes it easier to discern the impact categories with most need for impact reductions;
The science of cumulative exergy demand of exergy-based LCA of building eliminates the need for normalization and weighting; and
Bypassing the LCA to conduct exergy-based LCA of building reduces the time and effort involved.

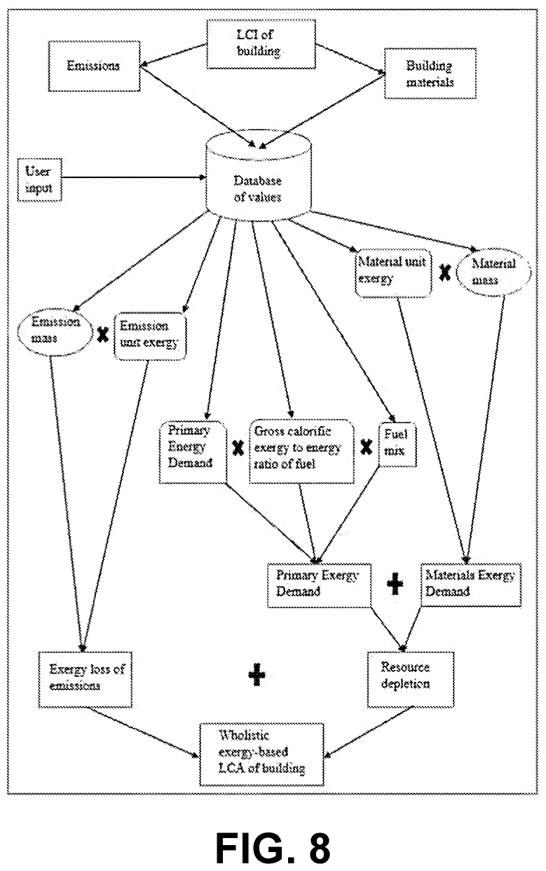

FIG. 8 is a flowchart illustrating an example of the integration of exergy-based LCA into LCA provisions in GBRS, which can guide the integration to overcome the identified challenges of whole building LCA provisions in GBRS. The flowchart design illustrates a new approach to make whole building LCA provisions in GBRS to be really wholistic as opposed to the current limitation of the provisions to a subset of environmental impacts. To represent wholistic LCA provisions in GBRS, the flowchart comprises the following:
Life cycle exergy loss of emissions to represent life cycle environmental impacts;
Inclusion of quality of fuel resource use, which is represented by primary exergy demand;
Inclusion of material resource use, which is represented by material exergy demand; and
A computation of wholistic exergy-based LCA of the building.

The “LCI” in FIG. 8 can be obtained from the building project information and from generic LCA commercial tools such as, e.g., Sima Pro and OpenLCA by inputting the needed project information. The “Database of values” stores and retrieves the data used to conduct the exergy-based LCA of the building such as the standard chemical exergy of emissions and materials, gross calorific exergy-to-energy ratio of various fuel sources, and user inputs such as emission mass, material mass, primary energy demand, fuel sources and percentages of their contributions or mix. This flowchart can be implemented in a software tool or application, in collaboration with organizations that manage GBRS, to maximize its potential to provide a wholistic LCA provisions in GBRS.

### Formulation of Exergy-based LCA Guidelines for Building Designers

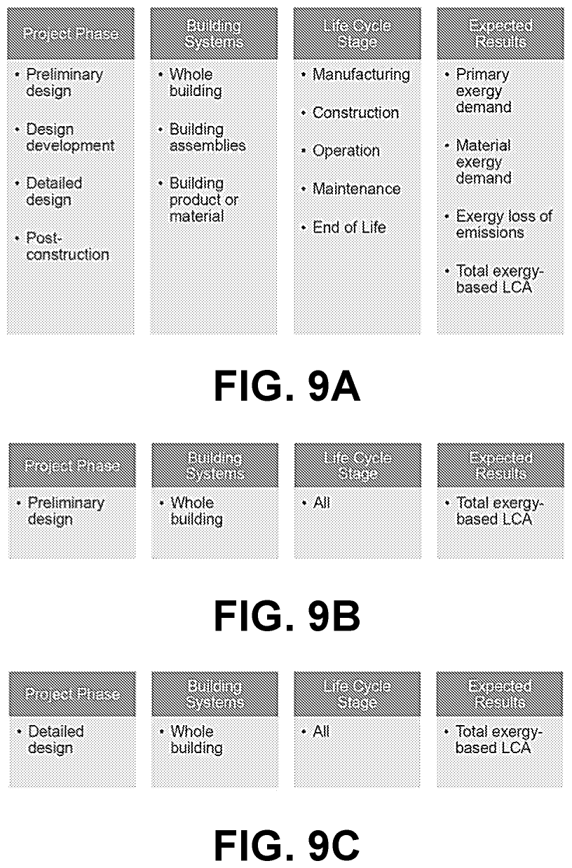

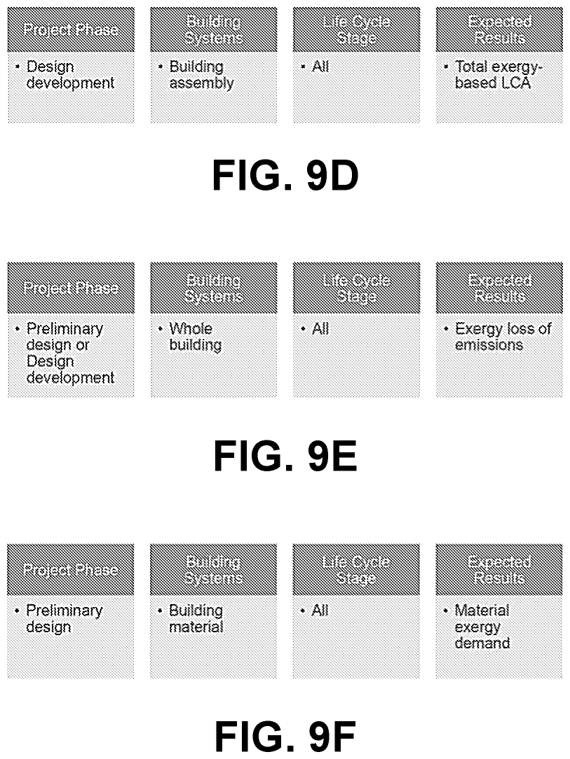

Guidelines to integrate exergy-based LCA into building design will now be presented. The goal is to provide building designers with a generic framework to perform exergy-based LCA of a building and to maximize its benefits in achieving sustainable design and construction. The intent of this section is to answer the question: Where and how can exergy-based LCA be used in building design? The guidelines provided here are adapted from the guidelines by the American Institute of Architects on integration of LCA in building design. Like LCA, any building-related exergy-based life cycle analysis can be defined by the following four variables:
Project phase at which exergy-based LCA is carried out;
Building systems of interest;
Included life cycle stages; and
Type of expected results.
   Each variable has a list of values. Various combinations of these values can lead to different scenarios of use for exergy-based LCA. FIG. 9A presents the generic framework from which various scenarios of use for Exe-LCA of buildings can be generated. The following describes five scenarios that can be generated from the generic framework.

Scenario One: Total Exergy-based LCA of Whole Building for All Life Cycle Stages to Optimize a Building Design during Preliminary Design Phase. FIG. 9B shows the variables for scenario one, which include preliminary design phase, whole building, all life cycle stages, and total exergy-based LCA.

A common act in every building design process is optimization of design alternatives during the schematic design phase. When the goal of the optimization is to select the most environmentally friendly option from the available alternatives, the exergy-based LCA analysis can be defined by the four variables shown in FIG. 9B. Since project information is minimal at this phase, the four variable values utilize an exergy-based LCA tool that takes approximate information and is easy to use. In addition, the tool is iterative to easily compare between building alternatives for the most environmentally friendly option. The developed automated calculation tool, ExeLCA, is best suited for this scenario.

Scenario Two: Total Exergy-based LCA of Whole Building for All Life Cycle Stages to Evaluate a Building Design during Detailed Design Phase. FIG. 9C shows the variables for scenario two, which include detailed design phase, whole building, all life cycle stages, and total exergy-based LCA.

At the detailed design phase and for a sustainable building design goal, the building designer may want to know more precisely, how their proposed design is better than the baseline design. This is especially the case for building designs undergoing a green building rating using GBRS such as LEED, and Green Globes. The only difference between scenarios one and two is the project phase at which the exergy-based LCA study is performed. At this phase, more precise project information is available. Thus, a more precise quantification can be carried out using the exergy-based LCA tool.

Scenario Three: Evaluating the Impact of a Building Assembly over a Building Life Cycle for Choice of Assembly. FIG. 9D shows the variables for scenario three, which include design development phase, building assembly, all life cycle stages, and total exergy-based LCA.

During design development phase, choices can be made between alternative assemblies of building components such as, e.g., walls and/or roof systems. This goal can be fulfilled by defining the exergy-based LCA study by the variable values presented in FIG. 9D. Like scenario one where building design alternatives can be compared, an iterative exergy-based LCA tool is used to easily compare between alternatives of building assemblies for the most environmentally friendly option. The developed automated calculation tool, ExeLCA, will be suited for this scenario.

Scenario Four. Evaluating a Specific Impact Category for the Whole Building. FIG. 9E shows the variables for scenario four, which include preliminary design or design development phase, whole building, all life cycle stages, and exergy loss of emissions.

A building's environmental sustainability study can be used to quantify and mitigate a specific impact category or categories for all life cycle stages. For example, some GBRS such as LEED and Green Globes need a percentage reduction be reported for at least three environmental impact categories, including global warming potential. In exergy-based LCA of buildings, this evaluation can be achieved using the exergy loss of emissions as the expected results for comparison. This scenario is defined by the variables shown in FIG. 9E, and which can be implemented using the developed exergy-based LCA automated calculation tool, ExeLCA.

Scenario Five: Evaluating Life Cycle Resource Depletion of Building Material. FIG. 9F shows the variables for scenario five, which include preliminary design phase, building material, all life cycle stages, and material exergy demand.

At the preliminary design phase, the building designer can evaluate the material resource depletion of the main alternative building materials that are considered for the design. Examples of alternative materials to be evaluated include, e.g., concrete, steel, aluminum, wood, etc. In exergy-based LCA of buildings, this evaluation can be achieved using the material exergy demand as the expected results for comparison. The developed automated calculation tool for exergy-based LCA of buildings can be utilized for this purpose.

In summary, issues in the practical implementation of exergy-based LCA in the industry include:
Development of a functional approach to incorporate other decision-making parameters into exergy-based LCA of buildings;
Motivation of building owners and clients who are interested in rating the environmental sustainability of their buildings;
Provision of enabling tool, based on exergy-based LCA method, to the management of GBRS to simplify the attainment of the conditions for whole building LCA in GBRS; and
Formulation of guidelines or better still, the provision of tool for building designers to use exergy-based LCA method for sustainable design and construction.

In this disclosure, a process model has been developed to show how LCC, which is one of the decision-making parameters, can be incorporated into exergy-based LCA of buildings. A flowchart has been created to present a new approach of how wholistic exergy-based LCA of buildings can be integrated into GBRS for whole building LCA. The new approach, by using LCI, eliminates the need to first conduct LCA before Exe-LCA while overcoming the identified challenges of whole building LCA provisions in GBRS.

The scenarios generated in the formulation of exergy-based LCA guidelines for building designers indicate that building designers, especially architects can now have options for use of exergy-based LCA method in building designs, like the options they have for LCA. In collaboration with building designers, the exergy-based LCA method can be implemented in a software tool or application that is suited for building designers.

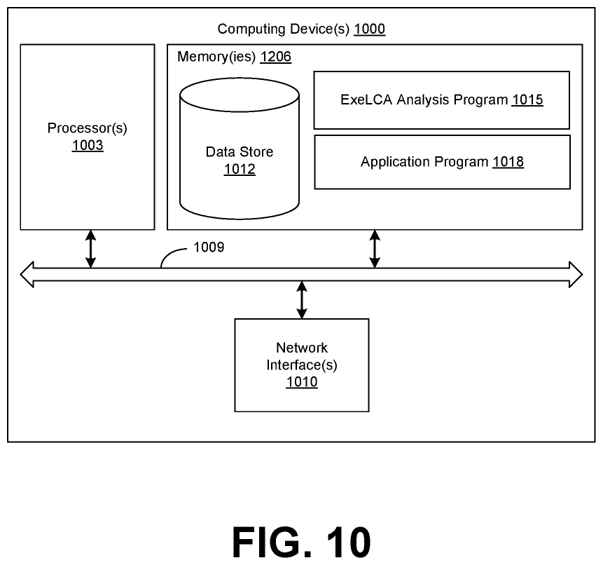

With reference to FIG. 10, shown is a schematic block diagram of a computing device 1000 that can be utilized to analyze buildings and their designs using the exergy-based LCA techniques. In some embodiments, among others, the computing device 1000 may represent a mobile device (e.g. a smartphone, tablet, computer, etc.). Each computing device 1000 includes at least one processor circuit, for example, having a processor 1003 and a memory 1006, both of which are coupled to a local interface 1009. To this end, each computing device 1000 may comprise, for example, at least one server computer or like device. The local interface 1009 may comprise, for example, a data bus with an accompanying address/control bus or other bus structure as can be appreciated.

In some embodiments, the computing device 1000 can include one or more network interfaces 1010. The network interface 1010 may comprise, for example, a wireless transmitter, a wireless transceiver, and a wireless receiver. As discussed above, the network interface 1010 can communicate to a remote computing device using a Bluetooth protocol. As one skilled in the art can appreciate, other wireless protocols may be used in the various embodiments of the present disclosure.

Stored in the memory 1006 are both data and several components that are executable by the processor 1003. In particular, stored in the memory 1006 and executable by the processor 1003 are an ExeLCA analysis program 1015, application program 1018, and potentially other applications. Also stored in the memory 1006 may be a data store 1012 and other data. In addition, an operating system may be stored in the memory 1006 and executable by the processor 1003.

It is understood that there may be other applications that are stored in the memory 1006 and are executable by the processor 1003 as can be appreciated. Where any component discussed herein is implemented in the form of software, any one of a number of programming languages may be employed such as, for example, C, C++, C#, Objective C, Java®, JavaScript®, Perl, PHP, Visual Basic®, Python®, Ruby, Flash®, or other programming languages.

A number of software components are stored in the memory 1006 and are executable by the processor 1003. In this respect, the term “executable” means a program file that is in a form that can ultimately be run by the processor 1003. Examples of executable programs may be, for example, a compiled program that can be translated into machine code in a format that can be loaded into a random access portion of the memory 1006 and run by the processor 1003, source code that may be expressed in proper format such as object code that is capable of being loaded into a random access portion of the memory 1006 and executed by the processor 1003, or source code that may be interpreted by another executable program to generate instructions in a random access portion of the memory 1006 to be executed by the processor 1003, etc. An executable program may be stored in any portion or component of the memory 1006 including, for example, random access memory (RAM), read-only memory (ROM), hard drive, solid-state drive, USB flash drive, memory card, optical disc such as compact disc (CD) or digital versatile disc (DVD), floppy disk, magnetic tape, or other memory components.

The memory 1006 is defined herein as including both volatile and nonvolatile memory and data storage components. Volatile components are those that do not retain data values upon loss of power. Nonvolatile components are those that retain data upon a loss of power. Thus, the memory 1006 may comprise, for example, random access memory (RAM), read-only memory (ROM), hard disk drives, solid-state drives, USB flash drives, memory cards accessed via a memory card reader, floppy disks accessed via an associated floppy disk drive, optical discs accessed via an optical disc drive, magnetic tapes accessed via an appropriate tape drive, and/or other memory components, or a combination of any two or more of these memory components. In addition, the RAM may comprise, for example, static random access memory (SRAM), dynamic random access memory (DRAM), or magnetic random access memory (MRAM) and other such devices. The ROM may comprise, for example, a programmable read-only memory (PROM), an erasable programmable read-only memory (EPROM), an electrically erasable programmable read-only memory (EEPROM), or other like memory device.

Also, the processor 1003 may represent multiple processors 1003 and/or multiple processor cores and the memory 1006 may represent multiple memories 1006 that operate in parallel processing circuits, respectively. In such a case, the local interface 1009 may be an appropriate network that facilitates communication between any two of the multiple processors 1003, between any processor 1003 and any of the memories 1006, or between any two of the memories 1006, etc. The local interface 1009 may comprise additional systems designed to coordinate this communication, including, for example, performing load balancing. The processor 1003 may be of electrical or of some other available construction.

Although the ExeCLA analysis program 1015 and the application program 1018, and other various systems described herein may be embodied in software or code executed by general purpose hardware as discussed above, as an alternative the same may also be embodied in dedicated hardware or a combination of software/general purpose hardware and dedicated hardware. If embodied in dedicated hardware, each can be implemented as a circuit or state machine that employs any one of or a combination of a number of technologies. These technologies may include, but are not limited to, discrete logic circuits having logic gates for implementing various logic functions upon an application of one or more data signals, application specific integrated circuits (ASICs) having appropriate logic gates, field-programmable gate arrays (FPGAs), or other components, etc. Such technologies are generally well known by those skilled in the art and, consequently, are not described in detail herein.

Also, any logic or application described herein, including the ExeLCA analysis program 1015 and the application program 1018, that comprises software or code can be embodied in any non-transitory computer-readable medium for use by or in connection with an instruction execution system such as, for example, a processor 1003 in a computer system or other system. In this sense, the logic may comprise, for example, statements including instructions and declarations that can be fetched from the computer-readable medium and executed by the instruction execution system. In the context of the present disclosure, a “computer-readable medium” can be any medium that can contain, store, or maintain the logic or application described herein for use by or in connection with the instruction execution system.

The computer-readable medium can comprise any one of many physical media such as, for example, magnetic, optical, or semiconductor media. More specific examples of a suitable computer-readable medium would include, but are not limited to, magnetic tapes, magnetic floppy diskettes, magnetic hard drives, memory cards, solid-state drives, USB flash drives, or optical discs. Also, the computer-readable medium may be a random access memory (RAM) including, for example, static random access memory (SRAM) and dynamic random access memory (DRAM), or magnetic random access memory (MRAM). In addition, the computer-readable medium may be a read-only memory (ROM), a programmable read-only memory (PROM), an erasable programmable read-only memory (EPROM), an electrically erasable programmable read-only memory (EEPROM), or other type of memory device.

Further, any logic or application described herein, including the ExeLCA analysis program 1015 and the application program 1018, may be implemented and structured in a variety of ways. For example, one or more applications described may be implemented as modules or components of a single application. Further, one or more applications described herein may be executed in shared or separate computing devices or a combination thereof. For example, a plurality of the applications described herein may execute in the same computing device 1000, or in multiple computing devices in the same computing environment. Additionally, it is understood that terms such as “application,” “service,” “system,” “engine,” “module,” and so on may be interchangeable and are not intended to be limiting.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

The term “substantially” is meant to permit deviations from the descriptive term that don't negatively impact the intended purpose. Descriptive terms are implicitly understood to be modified by the word substantially, even if the term is not explicitly modified by the word substantially.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. The term “about” can include traditional rounding according to significant figures of numerical values. In addition, the phrase “about ‘x’ to ‘y’” includes “about ‘x’ to about ‘y’”.

Therefore, at least the following is claimed:

1. A method, comprising:
obtaining building parameters of a building, the building parameters comprising material mass values of the building;
determining exergy-based life cycle assessment (Exe-LCA) values of the building based at least in part upon the building parameters, the Exe-LCA values comprising life cycle resource depletion, life cycle exergy loss of emissions and total Exe-LCA of the building; and
modifying a design of the building based upon the Exe-LCA values, the modification producing modified building parameters of the building.

2. The method of claim 1, wherein the life cycle resource depletion is determined based at least in part upon primary exergy demand (PExD) and materials exergy demand (MExD), wherein the MExD is based at least in part upon the material mass and material unit exergy.

3. The method of claim 2, wherein the PExD is based at least in part upon primary energy demand, percentage fuel combination and gross calorific exergy to energy ratio.

4. The method of claim 3, wherein the primary energy demand is determined by LCA.

5. The method of claim 1, wherein the life cycle exergy loss of emissions is determined based at least in part upon emission mass and emission unit exergy.

6. The method of claim 1, further comprising determining life cycle costing (LCC) values of the building, the LCC values comprising life cycle exergy cost of emission and total full environmental life cycle costing (feLCC) of the building.

7. The method of claim 6, wherein determining the LCC values comprises determining the life cycle exergy cost of emission based at least in part upon emission mass and emission unit exergy.

8. The method of claim 6, wherein determining the LCC values comprises determining the total feLCC based at least in part upon the life cycle exergy cost of emission and the life cycle resource depletion.

9. The method of claim 1, further comprising determining revised Exe-LCA values of the building based at least in part upon the modified building parameters, the revised Exe-LCA values comprising life cycle resource depletion, life cycle exergy loss of emissions and total Exe-LCA for the modified design of the building.

10. The method of claim 1, comprising providing modification recommendations based at least in part upon the Exe-LCA values, wherein the modification recommendations reduce the total Exe-LCA of the building.

11. A system, comprising:
at least one computing device comprising a processor and memory; and
an ExeLCA analysis program, where execution of the ExeLCA analysis program by the at least one computing device causes the at least one computing device to:
determine exergy-based life cycle assessment (Exe-LCA) values of a building based at least in part upon building parameters of the building, the building parameters comprising material mass values of the building, the Exe-LCA values comprising life cycle resource depletion, life cycle exergy loss of emissions and total Exe-LCA of the building; and
provide at least one modification of a design of the building based upon the Exe-LCA values, the at least one modification producing modified building parameters of the building.

12. The system of claim 11, wherein the life cycle resource depletion is determined based at least in part upon primary exergy demand (PExD) and materials exergy demand (MExD), wherein the MExD is based at least in part upon the material mass and material unit exergy.

13. The system of claim 11, wherein the life cycle exergy loss of emissions is determined based at least in part upon emission mass and emission unit exergy.

14. The system of claim 11, wherein execution of the ExeLCA analysis program causes the at least one computing to determine life cycle costing (LCC) values of the building, the LCC values comprising life cycle exergy cost of emission and total full environmental life cycle costing (feLCC) of the building.

15. The system of claim 14, wherein determining the LCC values comprises determining the life cycle exergy cost of emission based at least in part upon emission mass and emission unit exergy.

16. The system of claim 14, wherein determining the LCC values comprises determining the total feLCC based at least in part upon the life cycle exergy cost of emission and the life cycle resource depletion.

17. The system of claim 11, wherein execution of the ExeLCA analysis program causes the at least one computing to determine revised Exe-LCA values of the building based at least in part upon the modified building parameters, the revised Exe-LCA values comprising life cycle resource depletion, life cycle exergy loss of emissions and total Exe-LCA for the modified design of the building.

18. The system of claim 17, wherein execution of the ExeLCA analysis program causes the at least one computing to provide another modification of the design of the building based upon the revised Exe-LCA values, the other modification producing further modified building parameters of the building.

19. The system of claim 11, wherein the at least one modification reduces the total Exe-LCA of the building.
